(19) United States
(12) Patent Application Publication
(10) Pub. No.: US 2013/0330482 A1
(43) Pub. Date: Dec. 12, 2013

(54) CARBON-DOPED SILICON NITRIDE THIN FILM AND MANUFACTURING METHOD AND DEVICE THEREOF

(71) Applicant: NATIONAL CHIAO TUNG UNIVERSITY, Hsinchu City (TW)

(72) Inventors: Jihperng Leu, Taipei City (TW); Hung-En Tu, Chiayi City (TW); Wei-Gan Chiu, Kaohsiung City (TW)

(73) Assignee: NATIONAL CHIAO TUNG UNIVERSITY, Hsinchu City (TW)

(21) Appl. No.: 13/753,679

(22) Filed: Jan. 30, 2013

(30) Foreign Application Priority Data
Jun. 6, 2012 (TW) 101120340

(51) Int. Cl. C23C 16/34; C07F 7/10

(52) U.S. Cl. CPC C23C 16/345; C07F 7/10
USPC 427/579; 556/410; 556/409; 556/407; 106/287.11; 427/255.394; 118/723 R

(57) ABSTRACT

The present invention relates to carbon-doped silicon nitride thin film and forming method and device thereof The carbon-doped silicon nitride thin film is prepared by using a precursor having at least one of bis(dimethylamino)diethylsilane, N,N-Dimethyltrimethylsilylamine and a cyclic structure with a N—Si bond. The method for forming a carbon-doped silicon nitride thin film includes: providing a precursor having at least one of bis(dimethylamino)diethylsilane, N,N-Dimethyltrimethylsilylamine and a cyclic structure with a N—Si bond to form the carbon-doped silicon nitride thin film. The device for forming the carbon-doped silicon nitride thin film includes a reactor and a container with the aforementioned precursor coupled to the reactor.

The application claims the benefit of ROC Patent Application No. 101120340, filed on Jun. 6, 2012, in the Intellectual Property Office of Republic of China, the disclosures of which is incorporated by reference as if fully set forth herein.

### FIELD OF THE INVENTION

The present invention relates to a low-k carbon-doped silicon nitride thin film and a method and a device of forming the low-k carbon-doped silicon nitride thin film. More particularly, it relates to a low-k carbon-doped silicon nitride thin film formed by using a precursor selected from bis(dimethylamino)diethylsilane, N,N-Dimethyltrimethylsilylamine or a compound having a cyclic structure with an N-Si bond.

### BACKGROUND OF THE INVENTION

To reduce the capacitance in the backend interconnects, low dielectric constant material was first introduced as an interlayer dielectric (ILD). Meanwhile, silicon nitride was retained as the etch-stop and diffusion barrier layer in the dual damascene architecture, because of its excellent etch selectivity and barrier effectiveness, although its dielectric constant is relatively high, in a range at 6.5˜7.0. In order to further reduce the capacitance in the backend interconnects, the semiconductor industry has consistently kept trying to achieve lower effective dielectric constants, which involves a low-k ILD and a low-k etch-stop layer with a reduced thickness.

To reduce the k-value of silicon nitride films, silicon carbonitride (SiCₓN_{y}) thin films have been introduced as an etch stop/barrier layer, because of their low dielectric constant and their properties as effective barriers against Cu diffusion and drift. In addition to sputtering deposition and laser vapor deposition methods, silicon carbonitride films have been prepared by plasma-enhanced chemical vapor deposition (PECVD), using multi-precursors such as SiH₄+NH₃(or N₂)+CH₄ and SiH(CH₃)₃+NH₃.

However, the prior methods for forming the silicon carbonitride thin films have at least following shortcomings.

(1) The use of high plasma power density results in high charged defects and high plasma damage leading to a higher leakage current, namely the current conduction mechanism is dominated by Poole-Frenkel emission.

(2) The deposition must be performed under a temperature higher than 300° C., namely the deposition cannot be performed under a low temperature, so that the prior methods with high deposition temperatures cannot be applicable to flexible polymer substrates or the like due to the fact that polymer substrate will be damaged under the temperature of 300° C.

(3) The dielectric constant is relatively higher, at ˜5.5.

(4) The deposition rate cannot be precisely controlled.

Therefore, it would be useful to invent a forming method and device to circumvent all the above issues. In order to fulfill this need the inventors have proposed an invention “CARBON-DOPED SILICON NITRIDE THIN FILM AND MANUFACTURING METHOD AND DEVICE THEREOF.” The summary of the present invention is described as follows.

### SUMMARY OF THE INVENTION

In order to overcome the shortcomings of the prior art, the present invention provides a low-k carbon-doped silicon nitride thin film on a semiconductor substrate by using specific precursors so that the fabricating process can be performed by using a low plasma power density and the deposition is performed under a wide temperature range, which solves the problems of the charged defects and the plasma damage. In addition, due to the structure of the specific precursor of the present invention, the prepared carbon-doped silicon nitride thin film has not only a lower dielectric constant but also a better mechanical strength and dielectric strength, and it is applicable to act as the etch-stop and diffusion barrier layer for semiconductor fabrication.

According to the first aspect of the present invention, a method for forming a carbon-doped silicon nitride thin film is provided and includes a step of using a precursor having at least one selected from a group consisting of

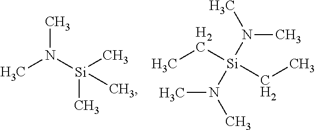

and a cyclic structure with an N—Si bond to form the carbon-doped silicon nitride thin film.

According to the second aspect of the present invention, a carbon-doped silicon nitride thin film is provided and is formed by using a precursor having at least one selected from a group consisting of

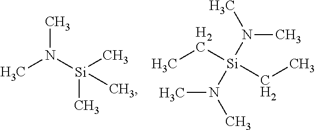

and a cyclic structure with an N—Si bond.

According to the third aspect of the present invention, a device for forming a carbon-doped silicon nitride thin film is provided and includes: a reactor; and a container coupled to the reactor and containing the above-mentioned precursor.

According to the fourth aspect of the present invention, a precursor for a chemical vapor deposition is provided and is selected from a group consisting of

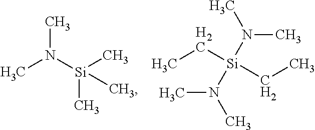

and a compound having a cyclic structure with an N—Si bond.

The foregoing and other features and advantages of the present invention will be more clearly understood through the following descriptions with reference to the drawings:

### BRIEF DESCRIPTION OF THE DRAWINGS

FIG. 1 shows the flow of the method for forming a carbon-doped silicon nitride thin film of the present invention.

FIG. 2 shows the structure of the embodiment of the present invention.

FIG. 3 shows the device for forming a carbon-doped silicon nitride thin film of the present invention.

FIG. 4 shows the wave number-absorbance curve diagram of FTIR spectra of the 1,3,5-trimethyl-1,3,5-trivinyl-cyclotrisilazane (VSZ) liquid precursor and SiCₓN_{y} films deposited at various deposition temperatures.

FIG. 5(a) shows the deposition temperature-elastic modulus curve diagram of SiCₓN_{y} films of the present invention.

FIG. 5(b) shows the deposition temperature-dielectric constant curve diagram of SiCₓN_{y} films of the present invention.

FIG. 6(a) shows the electric field-leakage current density curve diagram of SiCₓN_{y} films deposited at various deposition temperatures of the present invention.

FIGS. 6(b)˜(e) show Schottky emission mechanism fitting diagrams of SiCₓN_{y} films deposited at various deposition temperatures of the present invention.

### DETAILED DESCRIPTION OF THE PREFERRED EMBODIMENT

The present invention will now be described more specifically with reference to the following embodiments. It is to be noted that the following descriptions of preferred embodiments of this invention are presented herein for the aspect of illustration and description only; it is not intended to be exhaustive or to be limited to the precise from disclosed.

Please refer to FIG. 1 which shows the flow of the method for forming a carbon-doped silicon nitride thin film according to the present invention. The method for forming a carbon-doped silicon nitride thin film 100 includes the following steps.

Step 101: Provide a substrate. Preferably, the substrate is a semiconductor substrate, a polymer substrate or other prior substrate.

Step 102: Provide a precursor having at least one of bis(dimethylamino)diethylsilane, N,N-Dimethyltrimethylsilylamine and a cyclic structure with an N—Si bond. Formula 1 shows the structure of bis(dimethylamino)diethylsilane, and Formula 2 shows the structure of N,N-Dimethyltrimethylsilylamine. Preferably, the precursor is a single precursor selected therefrom.

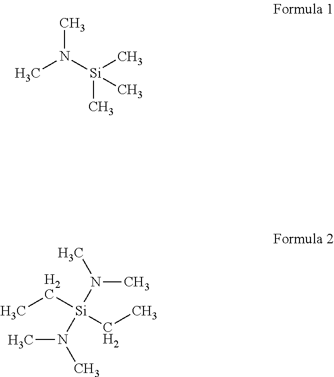

Step 103: Use a chemical vapor deposition process to form the carbon-doped silicon nitride thin film. Preferably, the carbon-doped silicon nitride thin film is a low-k carbon-doped silicon nitride thin film, and the chemical vapor deposition process is a plasma-enhanced chemical vapor deposition (PECVD) process.

Due to the structure of the aforementioned precursor, the carbon-doped silicon nitride thin film formed by the method 100 has cyclic structures and/or porous structures resulting in a relatively lower density, so that the dielectric constant will thus decrease. Moreover, because of the structure of the aforementioned precursor, the method 100 can perform the deposition under a temperature between 25° C. and 500° C. For plasma-enhanced chemical vapor deposition, it can be performed between 25° C. and 500° C. and under a low plasma power, for example a plasma power of 50W (power density of 0.15 W/cm³), to decrease the plasma damage and the charged defects. In addition, if the aforementioned structure is used as a single source precursor, it can be more precise to control the deposition rate, especially under a temperature less below 200° C. The cyclic structure with an N—Si bond of the present invention can be cyclic organosilazane. Preferably, the cyclic structure is 1,3,5-trimethyl-1,3,5-trivinyl-cyclotrisilazane (VSZ), N-methyl-aza-trimethylsilacyclopentane or the like. Formula 3 shows the structure of VSZ, and Formula 4 shows the structure of N-methyl-aza-trimethylsilacyclopentane.

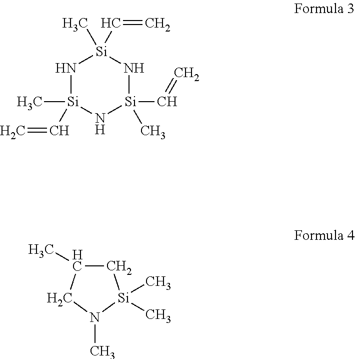

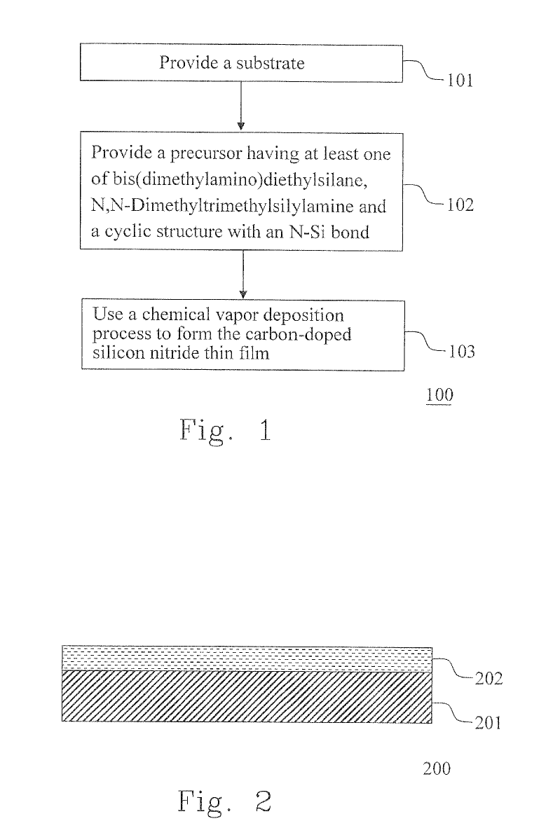

Please refer to FIG. 2 which is a schematic diagram showing the structure of the embodiment of the present invention. The embodiment is a semiconductor element 200. The semiconductor element 200 includes a first layer 201 and a carbon-doped silicon nitride layer 202. The first layer 201 can be a substrate, a dielectric layer, a metal layer or other material layer. The carbon-doped silicon nitride layer 202 is prepared by the method for forming a carbon-doped silicon nitride thin film 100 and is formed on the first layer 201 so as to have a lower dielectric constant. In addition, the carbon-doped silicon nitride layer 202 can be used as an etch stop layer, a passivation layer or a barrier layer.

Based on the aforementioned description and the method 100, it is seen that the important step for forming a carbon-doped silicon nitride thin film is to provide a precursor having at least bis(dimethylamino)diethylsilane, N,N-Dimethyltrimethylsilylamine and/or a cyclic structure with an N—Si bond, and preferably, the precursor is a single source precursor selected from the above three structures. Since the deposition can be performed under a low temperature, it is applicable to a polymer substrate or other substrates which would be damaged under a high temperature. For example, a low-k carbon-doped silicon nitride film deposited on a polymer substrate by using the method according to the present invention can be used as a passivation layer, a moisture barrier, or an antireflection layer. Preferably, the polymer substrate is made of optically transparent polyethylene terephthalate (PET) under a temperature in a range of 80° C.˜105° C., and the polymer substrate also can be made of other optically transparent material(s), such as optically transparent polymethylmethacrylate (PMMA), polyethylene naphthalate (PEN), polyethersulfone (PES), and/or polyimide (PI) with a temperature between 50° C. and 300° C. Moreover, due to the above advantages, the method for forming a carbon-doped silicon nitride thin film 100 and the carbon-doped silicon nitride thin film formed by the method can be applicable to semiconductor, optoelectronics and photoelectric industry, so as to fabricate optical or electronic components, such as a complementary metal oxide semiconductor (CMOS), a bipolar semiconductor element, an application specific integrated circuit (ASIC), flexible devices and so on. The flexible devices includes a flexible solar cell, a flexible organic light-emitting diode (OLED), a flexible display, a flexible sensor and so on.

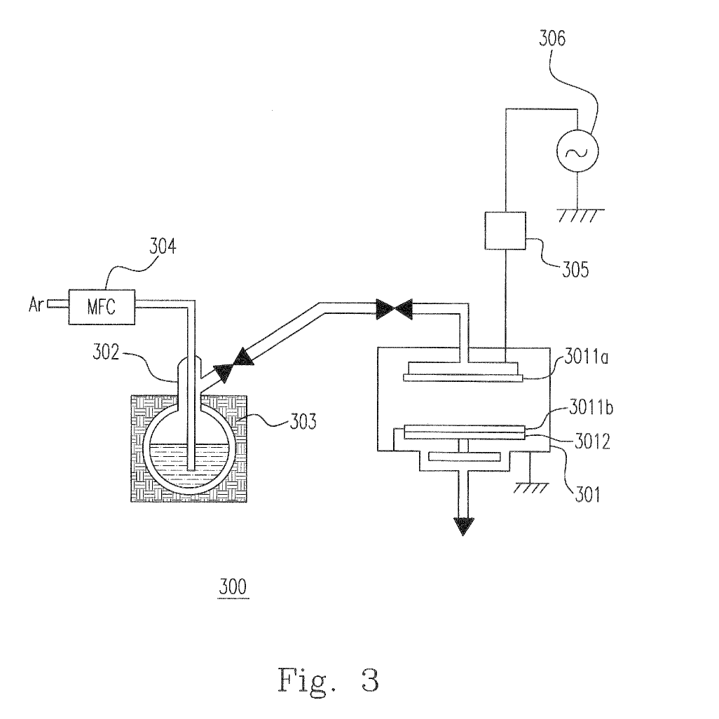

Please refer to FIG. 3 which is a schematic diagram showing the device for forming a carbon-doped silicon nitride thin film according to the present invention. The plasma chemical vapor deposition device 300 includes a chamber/reactor 301, a container 302, a first heater 303, a mass-flow controller (MFC) 304, a matching box 305 and an RF generator 306. The chamber/reactor 301 has electrodes 3011a and 3011b and a second heater 3012. The electrode 3011a has a shower head coupled to the RF generator 306 via the matching box 305. Preferably, the electrode spacing is 20 mm and the diameter of the electrode is 150 mm The container 302 is configured in the first heater 303 and coupled to the electrode 3011a, and contains a precursor having at least one of bis(dimethylamino)diethylsilane, N,N-Dimethyltrimethylsilylamine and a cyclic structure with an N—Si bond. The MFC 304 is used to control the flow rate of argon (Ar) entering the container 302, and the argon is used to carry the precursor to the electrode 3011a.

Taking a single source precursor, VSZ, for example, the flow rate of the argon carrier gas is 20 sccm, the deposition pressure is at 90 mTorr and the RF power is 50 W (power density=0.15 W/cm³). Under such operation, the bias is not necessary and the deposition temperatures can be varied in a range from the room temperature (approximately around 25° C.) to 400° C. The carbon-doped silicon nitride thin film prepared under such operation has a dielectric constant of 3.4˜4.6, breakdown strengths more than 3 MV/cm, elastic moduli of 21.0˜62.1 GPa and a density of 1.6˜2.0 g/cm³.

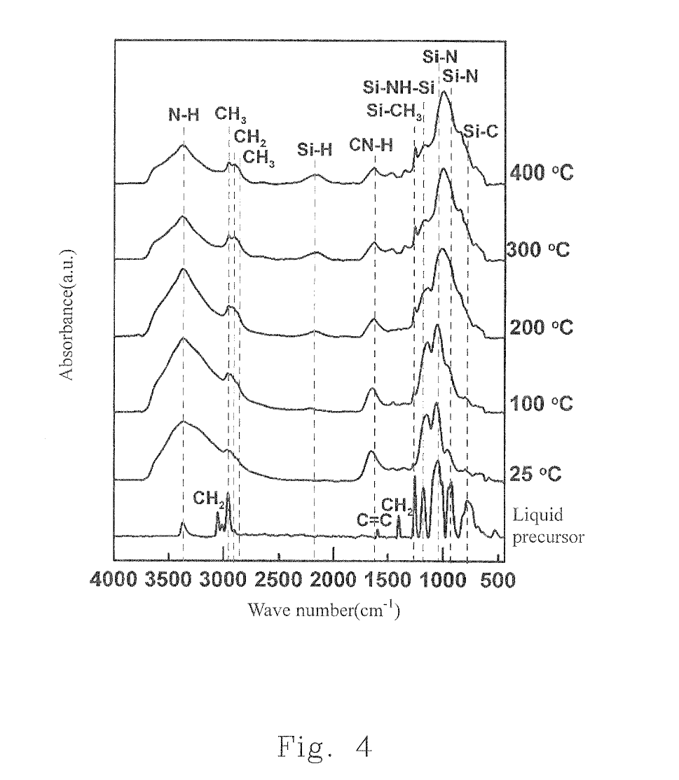

Please refer to FIG. 4 which shows the wave number-absorbance curve diagram of FTIR spectra of the VSZ liquid precursor and SiCₓN_{y} films deposited at various deposition temperatures. In FIG. 4, it could be known that at lower deposition temperatures (≦200° C.), the double bonds of the vinyl groups of the VSZ are broken and reform to a cross-linked structure, such as Si—(CH₂)ₙ—Si linkages, during the plasma deposition process, so that the SiCₓN_{y} films of the present invention will have a stronger mechanical structure. However, most of the cyclic VSZ structures are preserved to create free volume, i.e. void or pore, in the SiCₓN_{y} films, which results in a lower density and a lower dielectric constant. When the deposition temperature is raised to ≧300° C., the cyclic N—Si—N linkages are broken up and reform to a dense Si—N structure, with the desorption of CHₓ bonds. Furthermore, it can be seem from FIG. 4 that when the deposition temperature is more than 200° C., the cyclic structures will relatively decrease so as to form a dense structure, and thus the dielectric constant is higher.

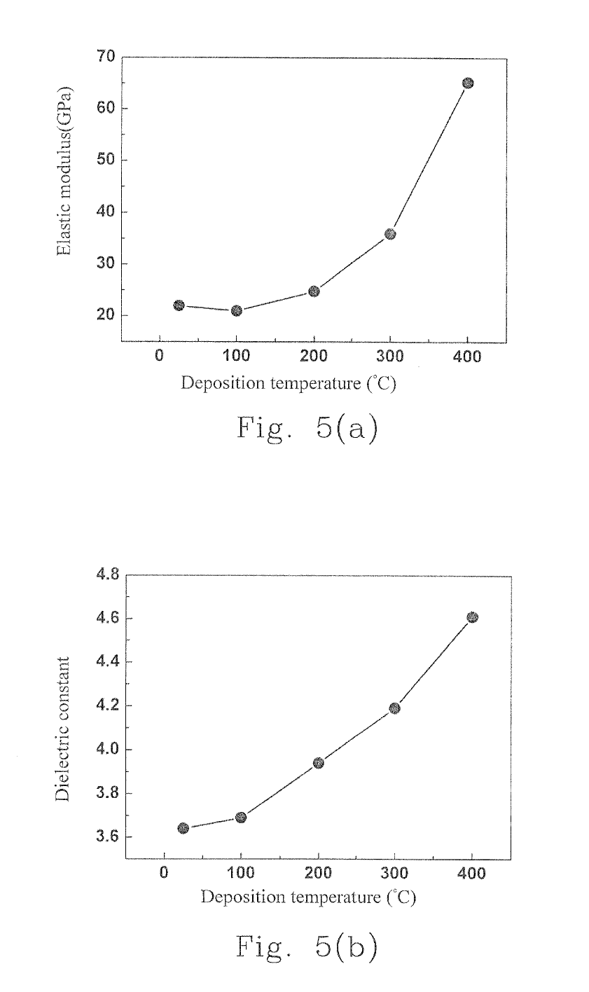

Please refer to FIGS. 5(a) and 5(b) which respectively show the deposition temperature-elastic modulus curve diagram and the deposition temperature-dielectric constant curve diagram of SiCₓN_{y} films of the present invention. In FIG. 5(a), it could be known that as the deposition temperature increases, due to the scission of the Si—N—Si linkages and the desorption of CHₓ bonds, the cross-linked structure is increased (please referring to FIG. 4), so that the elastic moduli are varied from 21.0 GPa to 65.2 GPa. In FIG. 5(b), it could be known that as the deposition temperature increases, due to the decreased void/porous structure, the dielectric constant increases from 3.6 to 4.6.

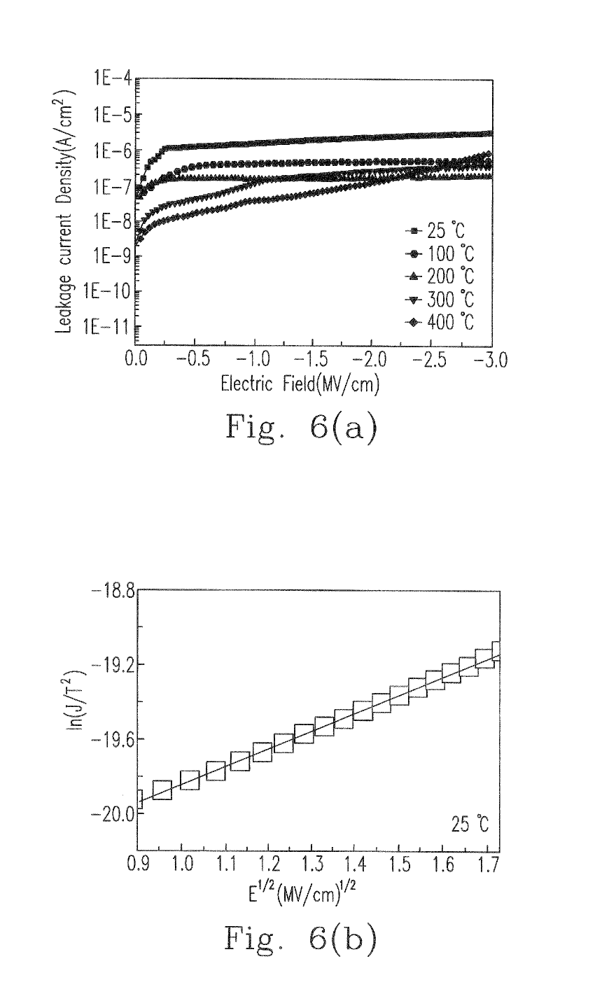

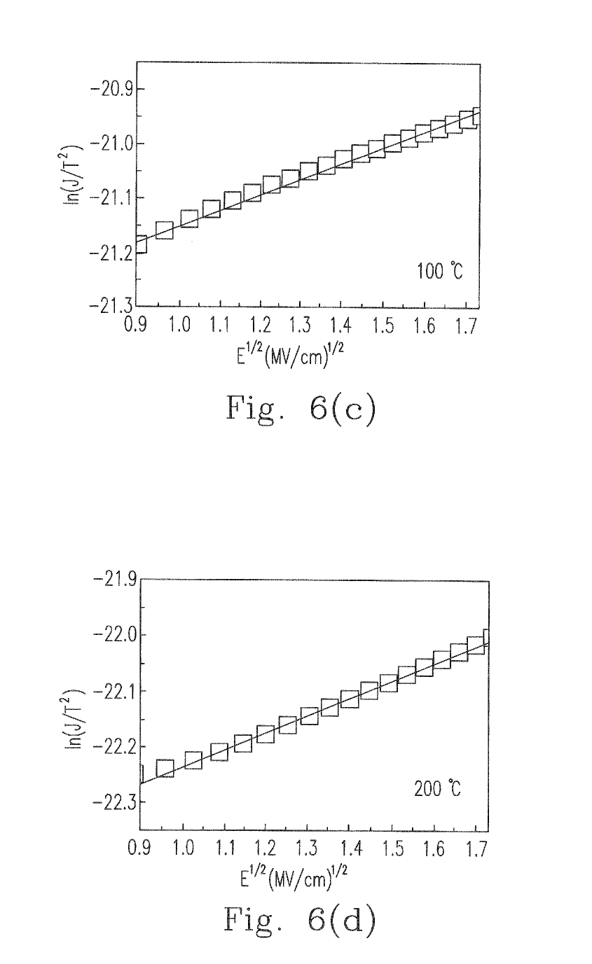

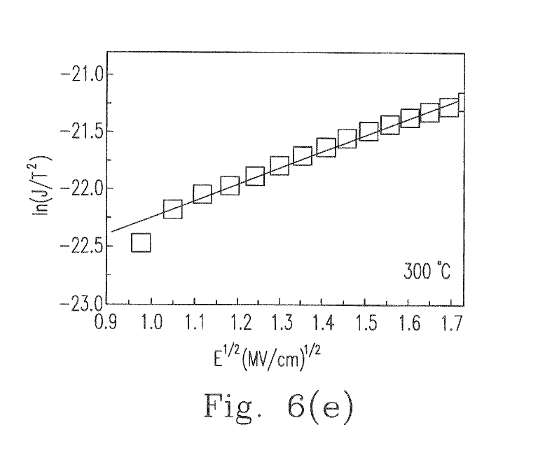

Please refer to FIGS. 6(a) and 6(b)˜(e). FIG. 6(a) shows the electric field-leakage current density curve diagram of SiCₓN_{y} films deposited at various deposition temperatures of the present invention, and FIGS. 6(b)˜(e) show Schottky emission mechanism fitting diagrams of SiCₓN_{y} films deposited at various deposition temperatures of the present invention. In FIG. 6(a), it could be known that as the deposition temperature increases, the leakage current density shows a decreasing trend from 1.5×10⁻⁶ to 4.0×10⁻⁸ A/cm² at the electric filed of 1 MV/cm. In addition, their breakdown strengths are all >3 MV/cm. In FIGS. 6(b)˜(e), it could be apparently recognized that the conduction mechanism of low-k SiCₓN_{y} films, deposited at 25° C.˜300° C. according to the present invention, is dominated by Schottky emission, and the graph also shows that there are few charged defects in SiCₓN_{y} films of the present invention, due to the fact that the damage of the present technical scheme of using a cyclic precursor and a lower plasma power density of 0.15 W/cm³ is less than that of the prior art.

There are still other embodiments, which are described as follows.

Embodiment 1: A method for forming a low-k carbon-doped silicon nitride thin film includes a step of providing a precursor being one selected from a group consisting of bis(dimethylamino)diethylsilane, N,N-Dimethyltrimethylsilylamine and a compound having a cyclic structure with an N—Si bond to form the low-k carbon-doped silicon nitride thin film.

Embodiment 2: In the method according to the above-mentioned embodiment 1, the precursor is a single source precursor.

Embodiment 3: In the method according to above-mentioned embodiment 1 or 2, the precursor has a double bond.

Embodiment 4: In the method according to any one of the above-mentioned embodiments 1˜3, the compound having the cyclic structure with the N—Si bond is one of

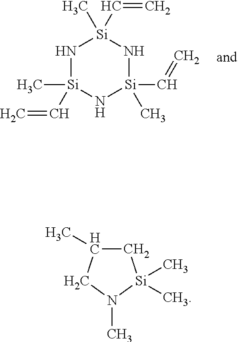

Embodiment 5: In the method according to any one of the above-mentioned embodiments 1˜4, the method further includes a step of using a plasma-enhanced chemical vapor deposition (PECVD) process to form the low-k carbon-doped silicon nitride thin film.

Embodiment 6: In the method according to any one of the above-mentioned embodiments 1˜5, the PECVD process is performed under a power density of 0.15 W/cm³.

Embodiment 7: In the method according to any one of the above-mentioned embodiments 1˜6, the PECVD process is performed under a temperature between 25° C. and 250° C.

Embodiment 8: In the method according to any one of the above-mentioned embodiments 1˜7, the PECVD process is performed under an argon carrier gas flow rate of 20 sccm.

Embodiment 9: In the method according to any one of the above-mentioned embodiments 1˜8, the PECVD process is performed under a precursor flow rate of 20 sccm.

Embodiment 10: A precursor for a chemical vapor deposition is the precursor as described in any one of the above-mentioned embodiments 1˜9.

Embodiment 11: A carbon-doped silicon nitride thin film is formed by using a chemical vapor deposition with the precursor as described in any one of the above-mentioned embodiments 1˜9.

Embodiment 12: A device for forming a carbon-doped silicon nitride thin film includes: a reactor having a first and a second electrodes; a container coupled to the reactor and containing a precursor being one selected from a group consisting of bis(dimethylamino)diethylsilane, N,N-Dimethyltrimethylsilylamine and a compound having a cyclic structure with an N—Si bond to form the carbon-doped silicon nitride thin film.

Embodiment 13: In the device according to the above-mentioned embodiment 12, the two electrodes have a distance of 20 mm therebetween.

Embodiment 14: In the device according to above-mentioned embodiment 12 or 13, the first electrode is coupled to the container and the reactor further comprises a heater coupled to the second electrode.

Embodiment 15: In the device according to any one of the above-mentioned embodiments 12˜14, the precursor is a single source precursor.

Embodiment 16: In the device according to any one of the above-mentioned embodiments 12˜15, the compound having the cyclic structure with an N—Si bond is one of

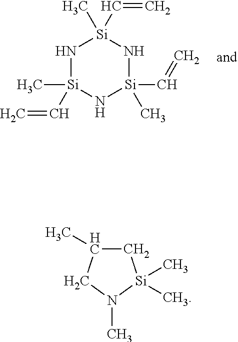

Embodiment 17: A method for forming a carbon-doped silicon nitride thin film includes a step of providing a precursor having at least one selected from a group consisting of

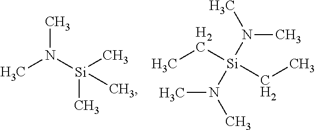

and a cyclic structure with an N—Si bond to form the carbon-doped silicon nitride thin film.

Embodiment 18: In the method according to the above-mentioned embodiment 17, the precursor is a single source precursor.

Embodiment 19: In the method according to above-mentioned embodiment 17 or 18, the cyclic structure with an N—Si bond is one of

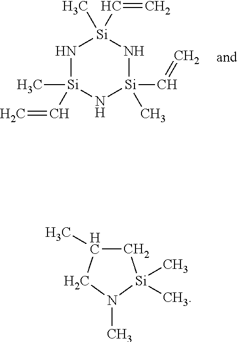

Embodiment 20: In the method according to any one of the above-mentioned embodiments 17˜19, the method further includes a step of using a plasma-enhanced chemical vapor deposition (PECVD) process to form the carbon-doped silicon nitride thin film.

While the invention has been described in terms of what are presently considered to be the most practical and preferred embodiments, it is to be understood that the invention need not be limited to the disclosed embodiments. On the contrary, it is intended to cover various modifications and similar arrangements included within the spirit and scope of the appended claims, which are to be accorded with the broadest interpretation so as to encompass all such modifications and similar structures. Therefore the above description and illustration should not be taken as limiting the scope of the present invention which is defined by the appended claims.

What is claimed is:

1. A method for forming a low-k carbon-doped silicon nitride thin film, comprising a step of providing a precursor being one selected from a group consisting of bis(dimethylamino)diethylsilane, N,N-Dimethyltrimethylsilylamine and a compound having a cyclic structure with an N—Si bond to form the low-k carbon-doped silicon nitride thin film.

2. The method as claimed in claim 1, wherein the precursor is a single source precursor.

3. The method as claimed in claim 1, wherein the precursor has a double bond.

4. The method as claimed in claim 1, wherein the compound having the cyclic structure with the N—Si bond is one of

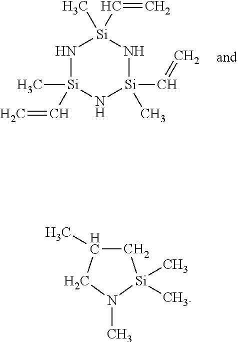

5. The method as claimed in claim 1 further comprising a step of using a plasma-enhanced chemical vapor deposition (PECVD) process to form the low-k carbon-doped silicon nitride thin film.

6. The method as claimed in claim 5, wherein the PECVD process is performed under a power density of 0.15 W/cm³.

7. The method as claimed in claim 5, wherein the PECVD process is performed under a temperature between 25° C and 250° C.

8. The method as claimed in claim 5, wherein the PECVD process is performed under an argon carrier gas flow rate of 20 sccm.

9. The method as claimed in claim 5, wherein the PECVD process is performed under a precursor flow rate of 20 sccm.

10. A precursor for a chemical vapor deposition being the precursor as claimed in claim 1.

11. A carbon-doped silicon nitride thin film being formed by using a chemical vapor deposition with the precursor as claimed in claim 1.

12. A device for forming a carbon-doped silicon nitride thin film, comprising:
a reactor having a first and a second electrodes;
a container coupled to the reactor and containing a precursor being one selected from a group consisting of bis(dimethylamino)diethylsilane, N,N-Dimethyltrimethylsilylamine and a compound having a cyclic structure with an N—Si bond to form the carbon-doped silicon nitride thin film.

13. The device as claimed in claim 12, wherein the two electrodes have a distance of 20 mm therebetween.

14. The device as claimed in claim 12, wherein the first electrode is coupled to the container and the reactor further comprises a heater coupled to the second electrode.

15. The device as claimed in claim 12, wherein the precursor is a single source precursor.

16. The device as claimed in claim 12, wherein the compound having the cyclic structure with an N—Si bond is one of

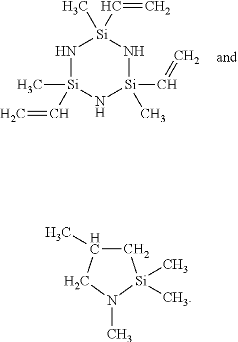

17. A method for forming a carbon-doped silicon nitride thin film, comprising a step of providing a precursor having at least one selected from a group consisting of 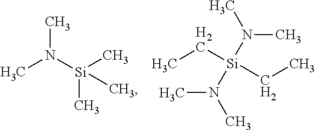
and a cyclic structure with an N—Si bond to form the carbon-doped silicon nitride thin film.

18. The method as claimed in claim 17, wherein the precursor is a single source precursor.

19. The method as claimed in claim 17, wherein the cyclic structure with an N—Si bond is one of

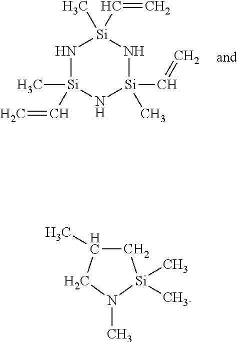

20. The method as claimed in claim 17 further comprising a step of using a plasma-enhanced chemical vapor deposition (PECVD) process to form the carbon-doped silicon nitride thin film.
